(19) United States
(12) Patent Application Publication
(10) Pub. No.: US 2025/0219510 A1
(43) Pub. Date: Jul. 3, 2025

(54) ELECTRONIC SENSOR FOR AN ELECTRIC MOTOR AND ELECTRIC MOTOR THEREOF

(71) Applicant: SIMOTOP GROUP S.P.A., VERONA VR (IT)

(72) Inventors: Guido COMAI, Budrio (Bologna) (IT); Alessandro ZANNA, San Lazzaro di Savena (Bologna) (IT); Andrea BENTIVOGLI, Granarolo dell'Emilia (Bologna) (IT); Stefano BARAGGIOLI, Ravenna (IT)

(21) Appl. No.: 18/850,510

(22) PCT Filed: Mar. 24, 2023
(86) PCT No.: PCT/IB2023/052932

§ 371 Date: Sep. 24, 2024

(30) Foreign Application Priority Data
Mar. 25, 2022 (IT) 102022000005927

(51) Int. Cl. H02K 11/35; H02K 5/18; H10N 10/13

(52) U.S. Cl. CPC H02K 11/35; H02K 5/18; H10N 10/13

(57) ABSTRACT

An electronic sensor for an electric motor is disclosed. The sensor includes an electrical energy accumulator configured to generate a charging voltage, a thermoelectric generator configured to generate a recovered voltage, an energy recovery circuit interposed between the thermoelectric generator and the electrical energy accumulator, and a short, medium or long distance signal transceiver. The energy recovery circuit is configured to receive the recovered voltage and to generate therefrom a charging current. The electrical energy accumulator is configured to be recharged at least in part by means of the charging current. The transceiver is supplied by means of the charging voltage.

### BACKGROUND

### Technical field

The present disclosure generally relates to the field of electric motors.

More particularly, the present disclosure concerns an electronic sensor for an electric motor capable of recovering electrical energy from the electric motor.

### Description of the related art

It is known to use sensors mounted on the frame of a motor, in order to measure operating parameters of the motor itself, such as for example the temperature thereof or the vibrations generated during operation.

The sensor comprises electronic components requiring a supply, which is provided by means of a battery mounted on the electronic board on which the same electronic components are mounted.

However, the battery life is limited and therefore it is necessary to replace it periodically, thus interrupting the operation of the motor for the time necessary for replacement and above all increasing the maintenance cost.

### BRIEF SUMMARY

The present disclosure concerns an electronic sensor for an electric motor as defined in appended claim 1 and the embodiments thereof described in dependent claims 2 to 11.

The Applicant has perceived that the electronic sensor according to the present disclosure makes it possible to prolong the life of the supply battery, reducing (in some cases eliminating) the number of maintenance interventions necessary for the replacement of the battery: in this way the number of interruptions of the operation of the electric motor is reduced and therefore the maintenance cost of the sensor itself is also reduced.

The present disclosure also relates to an electric motor as defined in the appended claim 12 and in a embodiment thereof described in dependent claim 13.

### DESCRIPTION OF THE SEVERAL VIEWS OF THE DRAWINGS

Additional features and advantages of the disclosure will become more apparent from the description which follows of an embodiment and the variants thereof, provided by way of example with reference to the appended drawings, in which:

FIG. 1 shows a perspective view of an electric motor according to an embodiment of the disclosure;

FIGS. 2A-2B show two perspective views of an electronic sensor for the electric motor of FIG. 1;

FIG. 3A shows another view of the electronic sensor mounted on the electric motor;

FIG. 3B shows in more detail a perspective view of a support element of the electronic sensor;

FIG. 4 shows another perspective view of the support for the electronic sensor;

FIG. 5 shows a block diagram of the electronic sensor of FIG. 2.

### DETAILED DESCRIPTION

It should be observed that, in the following description, identical or analogous blocks, components or modules are indicated in the figures with the same numerical references, even if they are shown in different embodiments of the disclosure.

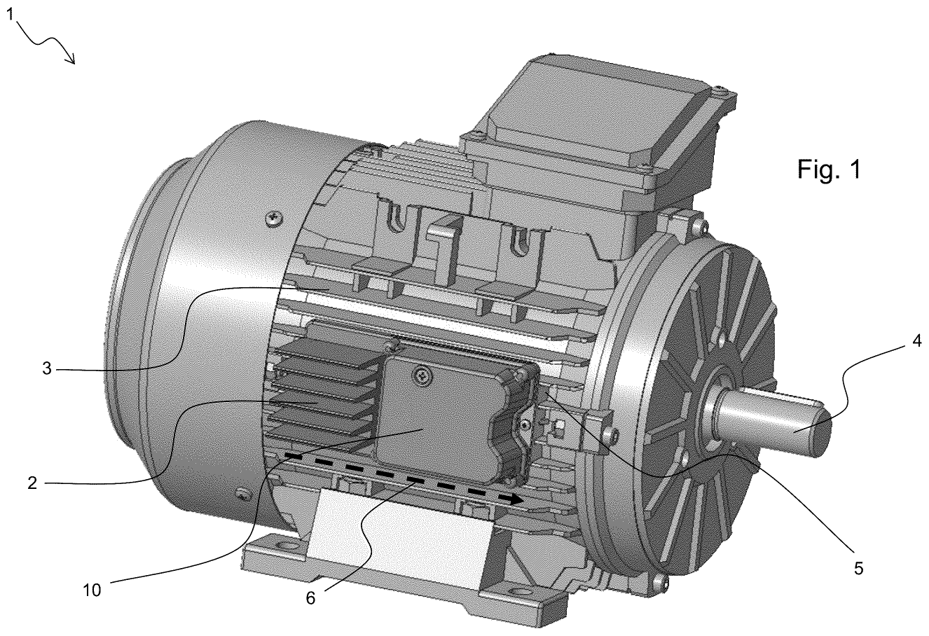

With reference to FIG. 1, a perspective view of an electric motor 1 according to an embodiment of the disclosure is shown.

For example, the electric motor can be of the three-phase asynchronous type with 4 kW power.

The electric motor 1 comprises a metal casing enclosing a stator and a rotor, the latter mechanically coupled to a rotating shaft 4 of the motor 1, and further comprises a heat sink 3 fixed to a portion of the casing, wherein the heat sink 3 is realized for example with a plurality of cooling fins.

The electric motor 1 further comprises an electronic sensor 10 fixed to the frame of the motor 1, in particular fixed in a seat obtained in the cooling fins 3 of the motor 1 by means of an aluminium wedge, so that a portion of a thermoelectric generator 13 (which will be illustrated in more detail later) is in contact with the heat generated by the motor 1 during its operation.

The electronic sensor 10 comprises electrical and electronic components that are enclosed within a housing made of plastic material and further comprises a heat sink 2 fixed to a portion of the electronic sensor 10, in particular to a portion of the thermoelectric generator 13.

In one embodiment, the heat sink 2 is realized with a plurality of cooling fins extending along a direction that is substantially parallel to the direction of extension of the cooling fins 3 of the motor 1.

Furthermore, an air flow is generated by means of a fan mounted in the motor 1 in order to cool further the cooling fins 3, so that the direction 6 of the generated air flow is substantially perpendicular to the direction of extension of the cooling fins 3 with respect to the casing of the motor 1: the generated air flow is also substantially perpendicular to the cooling fins 2 of the thermoelectric generator 13, thus further cooling the cold surface of the thermoelectric generator 13 itself.

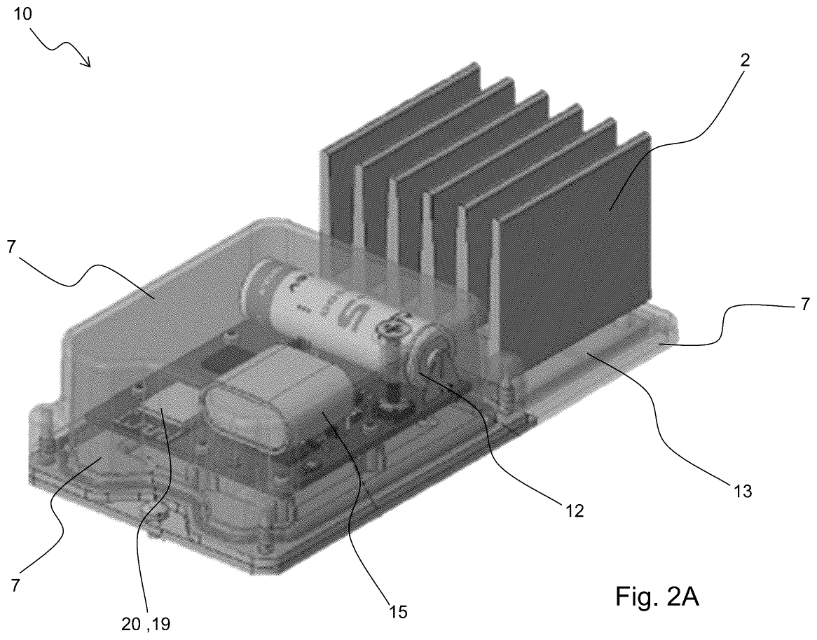

With reference to FIGS. 2A-2B, they show two top and bottom perspective views of the electronic sensor 10 for the electric motor 1, respectively.

It can be observed that the electronic sensor 10 comprises a casing 7 of plastic material enclosing therein a battery 12, an electrical energy accumulator 15 and the thermoelectric generator 13, wherein the casing 7 is defined below by a flat surface.

In particular, the casing 7 comprises at the bottom an opening which is closed by a flat metal sheet 9 of rectangular shape and by a plastic material element 9-1 of rectangular shape housed in an opening of the sheet 9 itself.

The sheet metal 9 has the function of thermally connecting a hot surface of the thermoelectric generator 13 to an upper surface 5-4 of a support element 5, which will be illustrated in more detail below.

The plastic material element 9-1 is positioned at the printed circuit board on which the electronic components of the sensor 10 are mounted and has the function of thermally isolating the electronic board from the motor 1.

The electronic sensor 10 and the battery 12 are mounted on the printed circuit board; instead the thermoelectric generator 13 is external to the board, but is electrically connected thereto by means of wired connections.

It is also possible to observe that the thermoelectric generator 13 has a laminar (i.e. flat) shape having two surfaces, wherein one surface (the “hot” surface) is thermally coupled with a portion of the motor 1 generating heat, while the other surface (“cold” surface) is thermally in contact with the heat sink 2: this generates a temperature difference between the hot and cold surface, therefore said temperature difference generates a flow of charges in the material interposed between the two hot and cold surfaces, thus generating a potential difference between two electrodes of the thermoelectric generator 13.

This phenomenon is called the “Seebeck effect” and is used to recharge the accumulator 15, as will be explained in more detail later.

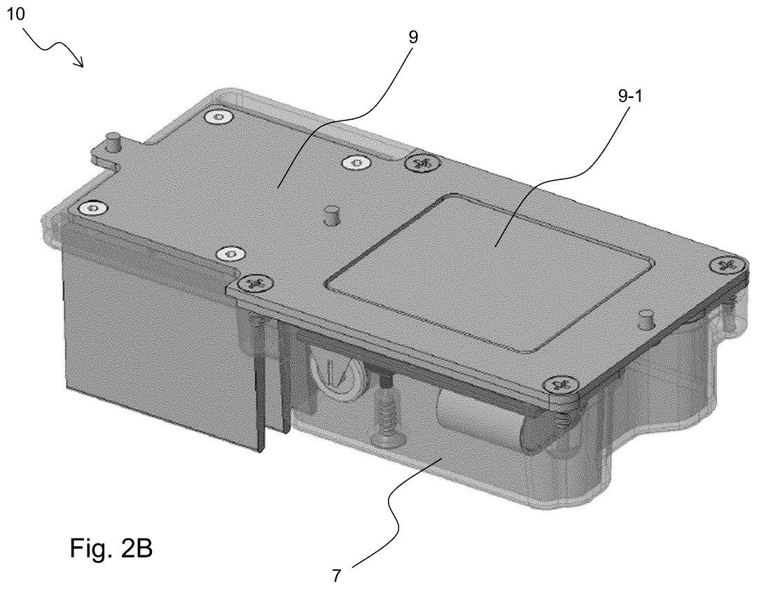

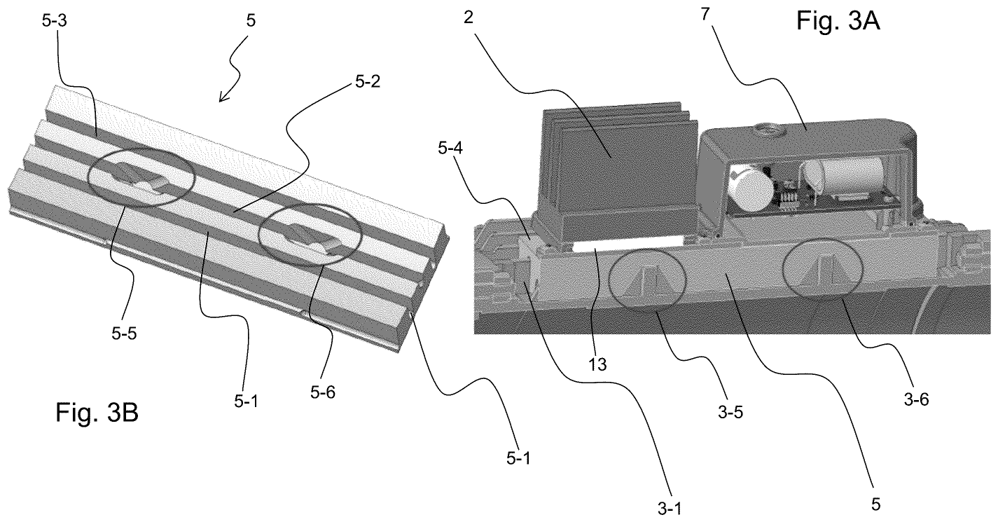

With reference to FIGS. 3A-3B, they shoes two views of the electronic sensor 10 when it is fixed to the electric motor 1.

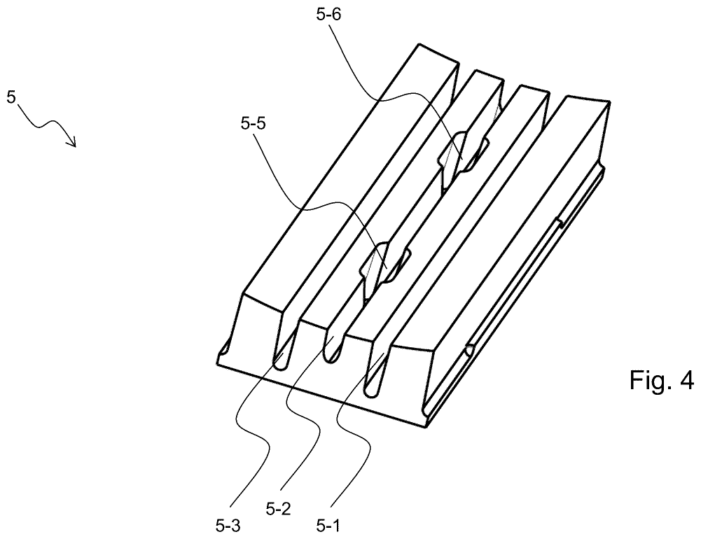

The sensor 10 comprises a support element 5 (see also FIGS. 3B and 4) having an upper surface 5-4 on which the flat lower surface of the casing 7 of the sensor 10 is fixed.

The support element 5 further comprises a second surface opposite to the first surface, wherein the second surface comprises three grooves 5-1, 5-2, 5-3 adapted to receive three respective cooling fins of the heat sink 3, wherein the shape of the grooves 5-1, 5-2, 5-3 of the support element 5 is counter-shaped with respect to the shape of the cooling fins of the heat sink 3 so that each cooling fin of the heat sink 3 is inserted in a respective groove between 5-1, 5-2, 5-3.

The second surface of the support element 5 further comprises two openings 5-5, 5-6 adapted to receive respectively two protruding elements 3-5, 3-6 of the heat sink 3, in order to allow the correct positioning of the sensor 10 with respect to the casing of the motor 1. In particular, FIG. 3A shows a cooling fin 3-1 of the heat sink 3, wherein the cooling fin 3-1 is for example inserted in the groove 5-1 of the support 5.

It can be observed that the thermoelectric generator 13 comprises a hot surface which is thermally coupled with the heat sink 3 by means of the metal sheet 9 and of the fins of the heat sink 3 inserted in the grooves 5-1, 5-2, 5-3 of the support element 5.

The use of the support element 5 with the grooves allows to increase the contact surface between the heat sink 3 and the thermoelectric generator 13, in order to obtain the hot surface of the thermoelectric generator 13.

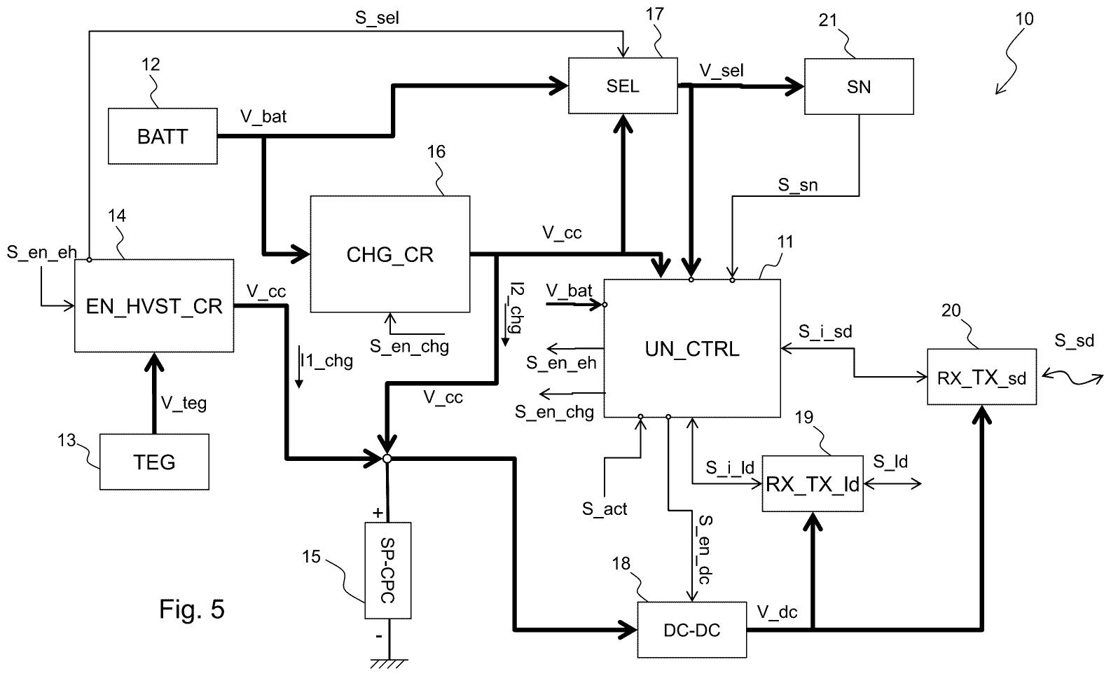

With reference to FIG. 5, a block diagram of the electronic sensor 10 for the electric motor 1 is shown.

The electronic sensor 10 (also referred to as “electronic system”) comprises a control unit 11, a battery 12, a thermoelectric generator 13, an energy recovery circuit 14, the electrical energy accumulator 15, a charging management circuit 16, a selector 17, a DC-DC converter 18, a long distance signal transceiver 19, a short distance signal transceiver 20 and one or more transducers 21.

The electronic sensor 10 has the function of recovering electrical energy from the motor 1 and the function of acquiring data indicative of the operation of the electric motor 1, by sending the data to a local electronic device or to a remote monitoring centre.

More particularly, the electronic sensor 10 has the function of optimizing the supply management of the long distance signal transceiver 19, of the short distance signal transceiver 20 and of the transducers 21, exploiting the electrical energy generated by means of the thermoelectric generator 13 in order to properly recharge the accumulator 15, thus minimizing the electrical energy absorbed by the battery 12, so as to greatly prolong its life.

The thermoelectric generator 13 has the function of generating a recovered voltage V_teg, converting thermal energy into electrical energy by means of the Seebeck effect as illustrated above.

In particular, the thermoelectric generator 13 comprises a positive terminal and a negative terminal, the latter connected for example to a ground reference voltage.

When there is a non-negligible temperature difference between the hot and cold surface of the thermoelectric generator 13, a voltage drop is generated between the positive terminal and the negative terminal of the thermoelectric generator 13.

For example, the temperature difference is comprised between 10 and 30degrees and the electric power generated by the thermoelectric generator 13 is comprised between 25 mW and 100 mW.

The thermoelectric generator 13 is realized for example with the component SP1848-27145.

The accumulator 15 has the function of accumulating electrical energy, generating a charging voltage V_cc to supply the long distance signal transceiver 19 and/or the short distance signal transceiver 20.

In one embodiment, the charging voltage V_cc may also be used to supply the control unit 11 and the transducers 21, as an alternative to the battery 12.

The accumulator 15 may be recharged (at least in part) by means of the electrical energy generated by the thermoelectric generator 13 through the electrical circuit 14, as will be explained in more detail below.

Furthermore, the accumulator 15 can be recharged (at least in part) also by means of the battery 12, as will be explained in more detail below.

The accumulator 15 is for example a rechargeable battery.

In one embodiment, the accumulator 15 is a supercapacitor having the function of accumulating electric charge, by means of the electrical energy generated by the thermoelectric generator 13 or by means of the battery 12.

The use of a supercapacitor has the advantage of providing a large amount of current in a short time, necessary to supply the long distance signal transceiver 19 and/or the short distance signal transceiver 20

The supercapacitor 15 is realized for example with the component BMOD0002-P005-B02 of the company Nesscap.

The energy recovery circuit 14 has the function of managing the recovery of electrical energy from the thermoelectric generator 13 and has the function of recharging at least in part the accumulator 15 by means of the electrical energy recovered from the thermoelectric generator 13, generating a first charging current I1_chg.

The energy recovery circuit 14 is electrically connected with the thermoelectric generator 13.

In particular, the energy recovery circuit 14 comprises a first input terminal adapted to receive the recovered voltage V_teg, a second input terminal adapted to receive a recovery enable signal S_en_eh and an output terminal adapted to generate the charging voltage V_cc and the first charging current I1_chg.

The energy recovery circuit 14 is such to switch between an active operating mode and an inactive operating mode, as a function of the recovery enable signal value S_en_eh, wherein in the active mode the energy recovery circuit 14 is configured to manage the recovery of electrical energy from the thermoelectric generator 13 and to at least partially recharge the accumulator 15, while in the inactive mode the energy recovery circuit 14 is switched off.

In one embodiment, the energy recovery circuit 14 further comprises an output terminal adapted to generate a selection signal S_sel, wherein the value of the selection signal S_sel is a function of the values of the battery voltage V_bat and of the charging voltage V_cc.

In particular, the selector 17 is configured to receive the selection signal S_sel having a first value (for example, a high logic value) that selects the charging voltage V_cc: in this case the selector 17 generates in output the selected voltage V_sel equal to the charging voltage V_cc. Conversely, the selector 17 is configured to receive the selection signal S_sel having a second value (e.g., a low logic value) that selects the battery voltage V_bat: in this case the selector 17 generates in output the selected voltage V_sel equal to the battery voltage V_bat.

Note that the presence of the energy recovery circuit 14 is not essential, i.e. the thermoelectric generator 13 can be directly connected to the accumulator 15, provided that the thermoelectric generator 13 and the accumulator 15 are suitably sized.

The energy recovery circuit 14 is realized for example with the electronic component bq25505 of the company Texas Instruments.

The charging management circuit 16 has the function of managing the recharge of the accumulator 15 by means of electrical energy extracted from the battery 12, in case of particular operating conditions of the electric motor 1, generating a second charging current I2_chg.

The charging management circuit 16 is electrically connected with the battery 12, the accumulator 15, the selector 17 and the control unit 11.

In particular, the charging management circuit 16 comprises a first input terminal adapted to receive the battery voltage V_bat, a second input terminal adapted to receive a charging enable signal S_en_chg and an output terminal adapted to generate the second charging current I2_chg to recharge at least in part the accumulator 15.

The charging management circuit 16 is such to switch between an inactive operating mode and an active mode as a function of the value of the charging enable signal S_en_chg, wherein:
in the active operating mode, the charging management circuit 16 is configured to provide current to at least partially recharge the accumulator 15, by means of electrical power extracted from the battery 12;
in the inactive operating mode, the charging management circuit 16 is deactivated, so no electric power is withdrawn from the battery 12.

The battery 12 has the function of supplying the control unit 11 and the transducers 21, in the case where the charging voltage V_cc at the ends of the accumulator 15 is not sufficient for supplying the same.

Therefore the following supply combinations are possible:
the long distance signal transceiver 19 and/or the short distance signal transceiver 20 are supplied by means of the accumulator 15, and also the control unit 11 and the transducers 21 are supplied by means of the accumulator 15;
the long distance signal transceiver 19 and/or the short distance signal transceiver 20 are supplied by means of the accumulator 15, while the control unit 11 and the transducers 21 are supplied by means of the battery 12.

Furthermore, the battery 12 is such to provide electrical power to at least partially recharge the accumulator 15, in the case where the thermoelectric generator 13 is such to generate a negligible voltage at the ends of its terminals.

The selector 17 has the function of generating a selected voltage V_sel selected between the battery voltage V_bat and the charging voltage V_cc, as a function of the value of a selection signal S_sel, which can be automatically generated by the energy recovery circuit 14 (as shown in FIG. 5) on the basis of predefined rules at the hardware level, or it can be generated by the control unit 11 on the basis of certain rules programmable by software.

The control unit 11 comprises:
a first input terminal adapted to receive the battery voltage V_bat;
a second input terminal adapted to receive the accumulated voltage V_cc;
a third input terminal adapted to receive one or more detection signals S_sn generated by the one or more transducers 21;
a first output terminal adapted to generate a recovery enable signal S_en_eh;
a second output terminal adapted to generate a charging enable signal S_en_chg;
a third output terminal adapted to generate a converter enable signal S_en_dc;
a first input/output terminal adapted to receive/transmit a first internal signal S_i_Id from/to the long distance signal transceiver 19;
a second input/output terminal adapted to receive/transmit a second internal signal S_i_sd from/to the short distance wireless signal transceiver 20.

In one embodiment, the control unit 11 further comprises a fourth output terminal adapted to generate the selection signal S_sel, wherein the value of the selection signal S_sel is a function of the values of the battery voltage V_bat and of the charging voltage V_cc.

In particular, in the case where the value of the charging voltage V_cc is greater than a threshold value, the control unit 11 is configured to generate the selection signal S_sel having a first value (for example, a high logic value) that selects the charging voltage V_cc: in this case the selector 17 generates in output the selected voltage V_sel equal to the charging voltage V_cc. Conversely, in the case where the value of the charging voltage V_cc is lower than a threshold value, the control unit 11 is configured to generate the selection signal S_sel having a second value (for example, a low logic value) that selects the battery voltage V_bat: in this case the selector 17 generates in output the selected voltage V_sel equal to the battery voltage V_bat.

Furthermore, the control unit 11 has the function of generating the value of the charging enable signal S_en_chg to enable or disable the operation of the charging management circuit 16, as a function of the state of charge of the accumulator 15.

Furthermore, the control unit 11 is configured to exchange data with the long distance signal transceiver 19 by means of the first internal signal S_i_Id and with the short distance wireless signal transceiver 20 by means of the second internal signal S_i_sd.

In one embodiment, the control unit 11 is further configured to measure the state of charge of the battery 12, in particular by means of monitoring the value of the charging voltage V_cc during the time interval in which the charging management circuit 16 is active to at least partially recharge the accumulator 15, absorbing electrical energy from the battery 12: in this way it is possible to monitor the state of charge of the battery 12, without using additional circuits. The control unit 11 then performs appropriate actions as a function of the state of charge of the battery 12, such as for example sending (by means of the transceiver 19 or 20) a notification on the next discharge of the battery in order to schedule a replacement intervention before the complete discharge of the battery 12.

The control unit 11 is realized for example as a microcontroller, in particular with the component STM32L4 of the company STMicroelectronics.

The DC-DC converter 18 has the function of converting the value of the continuous type charging voltage V_cc into another direct voltage value V_dc, so that the value of the direct supply voltage V_dc is compatible with the supply voltage values allowed by the long distance signal transceiver 19 and by the short distance wireless signal transceiver 20.

The DC-DC converter 18 is interposed between the accumulator 15 and the transceivers 19, 20 and comprises a first input terminal adapted to receive the charging voltage V_cc, a second input terminal adapted to receive the converter enable signal S_en_dc and an output terminal adapted to generate the direct supply voltage V_dc.

In particular, the DC-DC converter 18 is configured to switch between an active and a deactivated operating mode, as a function of the value of the converter enable signal S_en_dc, wherein in the active mode the DC-DC converter 18 is such to perform a conversion of the voltage level between input and output in boost (increase of voltage value) or buck mode (decrease of voltage level) and wherein in the deactivated mode the DC-DC converter 18 is switched off.

The long distance signal transceiver 19 is electrically connected with the control unit 11 and has the function of exchanging data with an electronic device external to the sensor 10 crossing a telecommunications network, such as for example a server or a remote monitoring unit.

In particular, the long distance signal transceiver 19 comprises an input terminal adapted to receive the direct voltage V_dc, a first input/output terminal carrying the first internal signal S_i_Id to exchange data with the control unit 11 and comprises a second input/output terminal carrying a long distance signal S_Id to exchange data with a medium-long distance telecommunications network, in particular data indicative of operating parameters of the electric motor 1, such as for example the temperature of the motor 1, the mechanical vibrations and/or acoustic waves generated by the motor 1 during its operation, the magnetic field generated externally to the motor 1 during its operation, the humidity external to the motor 1 and the operating time interval of the motor 1.

Similarly, the short distance wireless signal transceiver 20 is electrically connected with the control unit 11 and has the function of exchanging data with a mobile electronic device positioned in proximity to the sensor 10, such as for example a smartphone, a tablet or a portable personal computer.

In particular, the short distance signal transceiver 20 comprises an input terminal adapted to receive the direct voltage V_dc, a first input/output terminal carrying the second internal signal S_i_sd to exchange data with the control unit 11 and comprises a second input/output terminal carrying a short distance radio signal S_Id to exchange data with the local mobile electronic device, in particular data indicative of operating parameters of the electric motor 1, such as for example the temperature of the motor 1, the mechanical vibrations and/or acoustic waves generated by the motor 1 during its operation, the magnetic field generated externally to the motor 1 during its operation, the humidity external to the motor 1 and the operating time interval of the motor 1.

The short distance wireless signal is for example of the Wi-Fi or Bluetooth type (in particular, Bluetooth Low Energy).

It can be observed that the long distance signal transceiver 19 and the short distance wireless signal transceiver 20 are supplied only by the accumulator 15: in this way the electric power absorbed by the battery 12 is reduced to a minimum, since the transceivers 19, 20 are the components absorbing the greatest amount of current in a short time interval in order to perform a data exchange.

Otherwise, the control unit 11 and the transducers 21 are mainly supplied by the accumulator 15, but they can also be supplied by the battery 12 under particular conditions in which the state of charge of the accumulator 15 is not sufficient for supplying the control unit 11 and the transducers 21, since the transducers 21 have a small current absorption and also the control unit 11 is mainly in a stand-by state in which power consumption is minimized.

Some examples of conditions requiring the supply of the control unit 11 and of the transducers 21 by the battery 12 are as follows:
at the start of the electric motor 1;
insufficient generation of electrical energy by the thermoelectric generator 13, in case of special operating conditions of the electric motor 1.

In one embodiment, the sensor 10 further comprises an interruption circuit interposed between the output terminal of the battery 12 and the input terminals of the charging management circuit 16 and of the selector 17, wherein said interruption circuit has the function of interrupting the supply voltage of the control unit 11, of the transceiver 19 or 20 and of the transducer 21, in order to cancel the energy consumption of the battery 12. This may be useful for example at the end of the production process of the sensor 10 and during the storage period, i.e. before commissioning the sensor 10.

In one embodiment (not shown in the figures), the long distance signal transceiver 19 and/or the short distance signal transceiver 20 are supplied by means of the battery 12, and also the control unit 11 and the transducers 21 are supplied by means of the battery 12, in the case where the charging voltage V_cc at the ends of the accumulator 15 is not sufficient for supplying the same, in particular in a limited time interval waiting for the accumulator 15 to be sufficiently charged.

It will be described hereinafter the operation of the electric motor 1 during a first time interval, in which it is assumed that the accumulator 15 is realized with a supercapacitor 15 which is recharged at least in part by means of the electric power generated by the thermoelectric generator 13, while the state of charge of the battery 12 remains substantially unchanged.

In particular, during the first time interval heat is generated which is dissipated by means of the cooling fins 3.

The generated heat is transferred to the hot surface of the thermoelectric generator 13, while the cold surface thereof is maintained at a lower temperature than the hot surface, by means of the thermal contact with the cooling fins 2 and by means of the air flow flowing through the cooling fins 2: the temperature gradient between the cold and hot surface of the thermoelectric generator 13 generates a potential difference V_teg between the positive and negative terminal of the thermoelectric generator 13.

The control unit 11 receives the battery voltage V_bat and the charging voltage V_cc, makes a comparison between the value of the charging voltage V_cc and a threshold value, and detects that the value of the charging voltage V_cc is greater than the threshold value. Consequently, the control unit 11 generates the recovery enable signal S_en_eh having a value enabling the operation of the energy recovery circuit 14, which in turn generates the selection signal S_sel having a value indicating the selection of the charging voltage V_cc, therefore the selector 17 generates in output the selected voltage V_sel equal to the charging voltage V_cc: the control unit 11 is thus supplied by means of the charging voltage V_cc.

The energy recovery circuit 14 is active, receives on the first input terminal the potential difference V_teg and generates, as a function thereof, the first charging current I1_chg recharging at least in part the supercapacitor 15: it is assumed that the charge is sufficient so that the voltage drop V_cc at the ends of the supercapacitor 15 is not negligible (for example, V_cc=3.2 Volts).

The control unit 11 further generates the converter enable signal S_en_dc having a value enabling the active operating mode of the DC-DC converter 18.

The DC-DC converter 18 receives on the input terminal the direct charging voltage value V_cc and generates, as a function thereof, a direct voltage value V_dc, for example greater than the value of the charging voltage V_cc.

The long distance signal transceiver 19 receives on the input terminal the value of the direct voltage V_dc and is thus supplied by means of the electrical power stored in the supercapacitor 15: in this way the long distance signal transceiver 19 can exchange data with the telecommunications network.

Similarly, the short distance wireless signal transceiver 20 receives on the input terminal the value of the direct voltage V_dc and is thus supplied by means of the electrical power stored in the supercapacitor 15: in this way also the short distance wireless signal transceiver 20 can exchange data with the telecommunications network.

The transducers 21 receive the charging voltage V_cc and are thus supplied by means of the electric power stored in the supercapacitor 15.

Therefore during the first time interval the value of the charging voltage V_cc at the ends of the supercapacitor is sufficient for supplying the transceivers 19, 20, the control unit 11 and the transducers 21.

According to a variant, during the first time interval the selection signal S_sel is generated by the control unit 11, instead of by the energy recovery circuit 14.

The operation of the electric motor 1 during a second time interval will now be described, during which the supercapacitor 15 is recharged at least in part by means of electric power generated by the battery 12, which is thus partially discharged.

In particular, the control unit 11 receives the battery voltage V_bat and the charging voltage V_cc, makes a comparison between the value of the charging voltage V_cc and a threshold value, and detects that the value of the charging voltage V_cc is lower than the threshold value. Consequently, the control unit 11 generates the charging enable signal S_en_chg enabling the operation of the charging management circuit 16 and furthermore the control unit 11 generates the recovery enable signal S_en_eh disabling the operation of the energy recovery circuit 14, which in turn generates the selection signal S_sel having a value indicating the selection of the battery voltage V_bat, therefore the selector 17 generates in output the selected voltage V_sel equal to the battery voltage V_bat.

The control unit 11 is thus supplied by means of the battery voltage V_bat and also the transducers 21 are supplied by means of the battery voltage V_bat.

The charging management circuit 16 is active and operates by absorbing electrical power from the battery 12 and generating, as a function thereof, the second charging current I2_chg charging at least in part the supercapacitor 15.

Therefore the supercapacitor 15 is charged at least in part by means of the battery 12, while the thermoelectric generator 13 does not contribute to the recharging since the value of the voltage generated at its ends is too low.

The transceivers 19 and 20 are supplied by means of the direct voltage V_dc, which is a function of the charging voltage V_cc, with the difference (with respect to the first time interval) that at least a part of the electrical power accumulated in the supercapacitor 15 is absorbed by the battery 12, which then gets slightly discharged.

According to a variant, during the second time interval the selection signal S_sel is generated by the control unit 11, instead of by the energy recovery circuit 14.

The operation of the electric motor 1 during a third time interval will now be described, during which the supercapacitor 15 is charged in part by means of the electric power generated by the thermal generator 13 and in part by means of the electric power generated by the battery 12.

In particular, the control unit 11 receives the battery voltage V_bat and the charging voltage V_cc, makes a comparison between the value of the charging voltage V_cc and a threshold value, and detects that the value of the charging voltage V_cc is lower than the threshold value. Consequently, the control unit 11 generates the charging enable signal S_en_chg enabling the operation of the charging management circuit 16.

Furthermore, the control unit 11 generates the recovery enable signal S_en_eh enabling the operation of the energy recovery circuit 14, which in turn generates the selection signal S_sel having a value indicating the selection of the battery voltage V_bat, therefore the selector 17 generates in output the selected voltage V_sel equal to the battery voltage V_bat: the control unit 11 is thus supplied by means of the battery voltage V_bat and also the transducers 21 are supplied by means of the battery voltage V_bat.

The energy recovery circuit 14 is active, receives on the first input terminal the potential difference V_teg and generates, as a function thereof, the first charging current I1_chg recharging at least in part the supercapacitor 15.

The charging management circuit 16 is also active and operates by absorbing electrical power from the battery 12 and generating, as a function thereof, a charging current I2_chg charging at least in part the supercapacitor 15.

Therefore the supercapacitor 15 is charged in part by means of the battery 12 and in part by means of the thermoelectric generator 13, wherein the charging current I_chg comprises both a contribution given by the electrical power generated by the thermoelectric generator 13, and a contribution given by the electrical power of the battery 12, which then gets slightly discharged.

According to a variant, during the third time interval the selection signal S_sel is generated by the control unit 11, instead of by the energy recovery circuit 14.

In one embodiment, the sensor 10 is such to operate according to two operating modes:
an active mode, in which the control unit 11 is such to operate in order to execute a firmware program for the recovery of electrical energy by means of the thermoelectric generator 13 and/or of the battery 12 as illustrated above and to carry out a monitoring of operating parameters of the motor 1;
a stand-by mode, in which the control unit 11 is such to deactivate the operation of the charging management circuit 16, of the long distance signal transceiver 19, of the short distance wireless signal transceiver 20 and at least part of the transducers 21, for example by appropriately interrupting their supply.

In the stand-by mode the electric power consumption of the control unit 11 is therefore reduced to a minimum, thus increasing the life of the battery 12 and minimizing the energy absorption from the electrical energy accumulator 15.

The sensor 10 is such to switch between the stand-by mode and the active mode, in the case where the control unit 11 is such to receive an external activation command S_act or in the case where the control unit 11 is such to receive from the transducer 21 (connected to the control unit 11) a detection signal S_sn having an appropriate value: in this case the control unit 11 switches from the stand-by state to the active state, in order to execute the firmware program that takes in input the signal generated by the transducer 21 that has awakened the control unit 11.

The activation command S_act is for example an external signal generated by a user, for example by means of pressing a key positioned on the motor 1, wherein the key is connected with the electronic board on which the components of the sensor 10 are mounted.

In one embodiment, the control unit 11 is implemented with a microcontroller allowing to have a switching time between the stand-by mode and the active mode that is sufficiently low, such as to quickly detect possible critical defects present on the motor 1.

1-13. (canceled)

14. An electronic sensor for an electric motor, the sensor comprising:
an electrical energy accumulator configured to generate a charging voltage;
a thermoelectric generator configured to generate a recovered voltage;
an energy recovery circuit interposed between the thermoelectric generator and the electrical energy accumulator;
a short, medium or long distance signal transceiver;
wherein:
the energy recovery circuit is configured to receive the recovered voltage and to generate therefrom a charging current;
the electrical energy accumulator is configured to be recharged at least in part by means of the charging current;
the transceiver is supplied by means of the charging voltage.

15. The electronic sensor according to claim 14, further comprising:
a battery configured to generate a battery voltage;
a selector configured to generate a voltage selected between the charging voltage and the battery voltage, as a function of a selection signal;
a control unit supplied by means of said selected voltage, wherein the control unit is configured to generate a recovery enable signal indicative of an activation or deactivation of an operation of the energy recovery circuit;
wherein:
the control unit is configured to compare the charging voltage with respect to a voltage threshold value and to generate, as a function of said comparison, the recovery enable signal indicative of the activation of the operation of the energy
the energy recovery circuit is configured to receive the recovery enable signal indicative of said activation and to generate the selection signal indicative of the selection of the charging voltage;
the control unit is supplied by means of the selected voltage equal to the charging voltage.

16. The electronic sensor according to claim 15, further comprising a charging management circuit electrically connected to the battery, to the accumulator and to the selector, wherein the charging management circuit is configured to switch between an active and an inactive operating mode as a function of a charging enable signal, wherein:
the control unit is configured to compare the charging voltage with respect to a voltage threshold value and to generate, as a function of said comparison, the charging enable signal indicative of an activation of the operation of the charging management circuit;
the charging management circuit is configured to receive the battery voltage and to generate therefrom a further charging current;
the electrical energy accumulator is configured to be recharged at least in part by means of the charging current and of the further charging current.

17. The electronic sensor according to claim 16, wherein the energy recovery circuit is configured to generate the selection signal indicative of the selection of the battery voltage,
wherein the transceiver is supplied by means of the charging voltage,
and wherein the control unit is supplied by means of the selected voltage equal to the battery voltage.

18. The electronic sensor according to claim 16, wherein:
the control unit is configured to compare the charging voltage with respect to the voltage threshold value and to generate, as a function of said comparison, the recovery enable signal indicative of a deactivation of the operation of the energy
the charging management circuit is configured to receive the battery voltage and to generate therefrom the further charging current;
the electrical energy accumulator is configured to be recharged at least in part only by means of the further charging current;
the transceiver is supplied by means of the charging voltage;
the control unit is supplied by means of the selected voltage equal to the battery voltage.

19. The electronic sensor according to claim 15, wherein, alternatively:
the energy recovery circuit is configured to generate the selection signal indicative of the selection of the charging voltage or of the battery voltage;
the control unit is configured to generate the selection signal indicative of the selection of the charging voltage or of the battery voltage.

20. The electronic sensor according to claim 14, wherein the electrical energy accumulator is a supercapacitor.

21. The electronic sensor according to claim 14, wherein the thermoelectric generator comprises a hot surface adapted to be in thermal contact with a hot portion of a motor casing and comprises a cold surface adapted to be in contact with a heat sink, wherein the thermoelectric generator is configured to generate a voltage drop at its ends which is a function of a temperature difference between the hot and cold surface.

22. The electronic sensor according to claim 14, further comprising a transducer adapted to generate a detection signal of operating parameters associated with the electric motor, including a temperature thereof or vibrations,
wherein the transducer is supplied, alternatively, by means of the charging voltage or of a battery voltage.

23. The electronic sensor according to claim 22, wherein a control unit is configured to operate:
in an active mode, in which the control unit is configured to execute a firmware program for charging the electrical energy accumulator;
in a stand-by mode, in which the control unit is configured to switch from the stand-by mode to the active mode in case of receiving the detection signal carrying motor operating parameters or in case of receiving an external activation command.

24. The electronic sensor according to claim 15, further comprising a cutoff circuit interposed between the battery and a charging management circuit and the selector, wherein the cutoff circuit is configured to disconnect the supply voltage of a control unit, of the transceiver and of a transducer.

25. An electric motor comprising an electronic sensor, the sensor comprising:
an electrical energy accumulator configured to generate a charging voltage;
a thermoelectric generator configured to generate a recovered voltage;
an energy recovery circuit interposed between the thermoelectric generator and the electrical energy accumulator;
a short, medium or long distance signal transceiver;
wherein:
the energy recovery circuit is configured to receive the recovered voltage and to generate therefrom a charging current;
the electrical energy accumulator is configured to be recharged at least in part by means of the charging current;
the transceiver is supplied by means of the charging voltage;
the motor comprising a casing, a first heat sink fixed to a portion of the casing and a second heat sink fixed to the thermoelectric generator of the sensor,
wherein the electronic sensor is fixed to a portion of the casing,
wherein the thermoelectric generator has a laminar shape comprising a first surface in thermal contact with said portion of the casing and a second surface in thermal contact with the second heat sink of the sensor.

26. The electric motor according to claim 25, wherein:
the first heat sink comprises a plurality of protruding cooling fins;
the sensor comprises a support element comprising a surface having a plurality of grooves adapted to receive the plurality of cooling fins of the first heat sink.

27. The electronic sensor according to claim 17, wherein:
the control unit is configured to compare the charging voltage with respect to the voltage threshold value and to generate, as a function of said comparison, the recovery enable signal indicative of a deactivation of the operation of the energy recovery circuit;
the charging management circuit is configured to receive the battery voltage and to generate therefrom the further charging current;
the electrical energy accumulator is configured to be recharged at least in part only by means of the further charging current;
the transceiver is supplied by means of the charging voltage;
the control unit is supplied by means of the selected voltage equal to the battery voltage.

28. The electronic sensor according to claim 16, wherein, alternatively:
the energy recovery circuit is configured to generate the selection signal indicative of the selection of the charging voltage or of the battery voltage;
the control unit is configured to generate the selection signal indicative of the selection of the charging voltage or of the battery voltage.

29. The electronic sensor according to claim 15, wherein the thermoelectric generator comprises a hot surface adapted to be in thermal contact with a hot portion of a motor casing and comprises a cold surface adapted to be in contact with a heat sink, wherein the thermoelectric generator is configured to generate a voltage drop at its ends which is a function of a temperature difference between the hot and cold surface.

30. The electric motor according to claim 25, wherein the electronic sensor further comprises:
a battery configured to generate a battery voltage;
a selector configured to generate a voltage selected between the charging voltage and the battery voltage, as a function of a selection signal;
a control unit supplied by means of said selected voltage, wherein the control unit is configured to generate a recovery enable signal indicative of an activation or deactivation of an operation of the energy recovery circuit;
wherein:
the control unit is configured to compare the charging voltage with respect to a voltage threshold value and to generate, as a function of said comparison, the recovery enable signal indicative of the activation of the operation of the energy recovery circuit;
the energy recovery circuit is configured to receive the recovery enable signal indicative of said activation and to generate the selection signal indicative of the selection of the charging voltage;
the control unit is supplied by means of the selected voltage equal to the charging voltage.

31. The electric motor according to claim 30, further comprising a charging management circuit electrically connected to the battery, to the accumulator and to the selector, wherein the charging management circuit is configured to switch between an active and an inactive operating mode as a function of a charging enable signal, wherein:
the control unit is configured to compare the charging voltage with respect to a voltage threshold value and to generate, as a function of said comparison, the charging enable signal indicative of an activation of the operation of the charging management circuit;
the charging management circuit is configured to receive the battery voltage and to generate therefrom a further charging current;
the electrical energy accumulator is configured to be recharged at least in part by means of the charging current and of the further charging current.

32. The electric motor according to claim 31, wherein the energy recovery circuit is configured to generate the selection signal indicative of the selection of the battery voltage,
wherein the transceiver is supplied by means of the charging voltage,
and wherein the control unit is supplied by means of the selected voltage equal to the battery voltage.
